(19) United States
(12) Patent Application Publication
(10) Pub. No.: US 2026/0173811 A1
(43) Pub. Date: Jun. 18, 2026

(54) ELECTROSTATIC CHUCK

(71) Applicant: TOTO LTD., Fukuoka (JP)

(72) Inventors: Masafumi IKEGUCHI, Fukuoka (JP); Kouta KOBAYASHI, Fukuoka (JP); Jun SHIRAISHI, Fukuoka (JP)

(73) Assignee: TOTO LTD., Fukuoka (JP)

(21) Appl. No.: 19/410,293

(22) Filed: Dec. 5, 2025

(30) Foreign Application Priority Data
Dec. 18, 2024 (JP) 2024221318

(51) Int. Cl. H01L 21/683; H01J 37/32

(52) U.S. Cl. CPC H10P 72/722; H01J 37/32715; H01J 2237/2007

(57) ABSTRACT

An electrostatic chuck includes a dielectric substrate including a first part which includes a surface as a placement surface, and a second part protruding from an outer peripheral end of the first part further toward an outer peripheral side and being thinner than the first part. A base plate joined to the dielectric substrate. A joining layer joins the dielectric substrate with the base plate. The joining layer includes a first joining layer, and a second joining layer surrounding the first joining layer in an annular shape on an outer peripheral side. A thermal conductivity of the second joining layer is higher than a thermal conductivity of the first joining layer. In the electrostatic chuck, an end part on an inner peripheral side of the second joining layer is located at a position not overlapping with the first part in top view.

### CROSS-REFERENCE TO RELATED APPLICATION

This application is based upon and claims the benefit of priority from Japanese Patent Application No. 2024-221318 filed on Dec. 18, 2024, the entire contents of which are incorporated herein by reference.

### FIELD

The present invention relates to an electrostatic chuck.

### BACKGROUND

For example, in a semiconductor manufacturing apparatus including an etching apparatus, an electrostatic chuck is provided as an apparatus configured to attract and hold a wafer such as a silicon wafer to be processed. The electrostatic chuck includes a dielectric substrate to which an attraction electrode is provided and a base plate which supports the dielectric substrate, and has a configuration in which these are joined to each other. When a voltage is applied to the attraction electrode, an electrostatic force is generated, and the wafer placed on the dielectric substrate is attracted and held.

As disclosed in Japanese Patent Laid-Open No. 2020-23088, the dielectric substrate and the base plate are joined to each other via a joining layer such as a cured silicone adhesive, for example.

### SUMMARY

During processing, fluctuation in an in-plane temperature distribution of the wafer is required to be reduced as much as possible. As a measure for reducing fluctuation in the in-plane temperature distribution, the present inventors have examined making a material of the joining layer different for each position.

The present invention has been made in view of such an issue and is aimed to provide an electrostatic chuck in which fluctuation in an in-plane temperature distribution of a wafer can be reduced.

To address the above-mentioned issue, the electrostatic chuck according to the present invention includes: a dielectric substrate including a first part which includes a placement surface on which an object to be processed is placed, and a second part protruding from an outer peripheral end of the first part further toward an outer peripheral side and being thinner than the first part; a base plate joined to the dielectric substrate; and a joining layer joining the dielectric substrate with the base plate. The joining layer includes a first joining layer, and a second joining layer surrounding the first joining layer in an annular shape on an outer peripheral side. A thermal conductivity of the second joining layer is higher than a thermal conductivity of the first joining layer. When the electrostatic chuck is viewed from a direction perpendicular to the placement surface, an end part on an inner peripheral side of the second joining layer is located at a position not overlapping with the first part.

During processing on the wafer, a temperature of an outer peripheral side part is likely to increase as compared with an inner peripheral side part of the wafer. Additionally, an annular member that is called a “focus ring” or the like is placed right above the second part, and a temperature of the annular member is also likely to increase during the process. When the temperature of the annular member increases, due to the influence thereof, the temperature of the outer peripheral side part of the wafer may further increase.

In the electrostatic chuck having the above configuration, a part of the dielectric substrate supporting the annular member is joined to the base plate via the second joining layer having a high thermal conductivity. In such a configuration, a temperature increase of the annular member is suppressed, and a temperature increase of the outer peripheral side part of the wafer due to the influence thereof is also suppressed, so that it is possible to reduce fluctuation in an in-plane temperature distribution of the wafer.

According to the present invention, it is possible to provide an electrostatic chuck which can reduce fluctuation in the in-plane temperature distribution of the wafer.

### BRIEF DESCRIPTION OF THE DRAWINGS

FIG. 1 is a cross sectional view schematically illustrating a configuration of an electrostatic chuck according to a first embodiment;

FIG. 2 is a diagram illustrating a configuration of a joining layer included in the electrostatic chuck in FIG. 1; and

FIG. 3 is a cross sectional view schematically illustrating a configuration of the electrostatic chuck according to a second embodiment.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

A first embodiment will be described. An electrostatic chuck 10 according to the present embodiment is configured to attract and hold a wafer W set as a process target by an electrostatic force inside a semiconductor manufacturing apparatus such as, for example, an etching apparatus which is not illustrated in the drawing. The wafer W corresponds to an “object to be processed”, and is a silicon wafer, for example. The electrostatic chuck 10 may be used in an apparatus other than the semiconductor manufacturing apparatus.

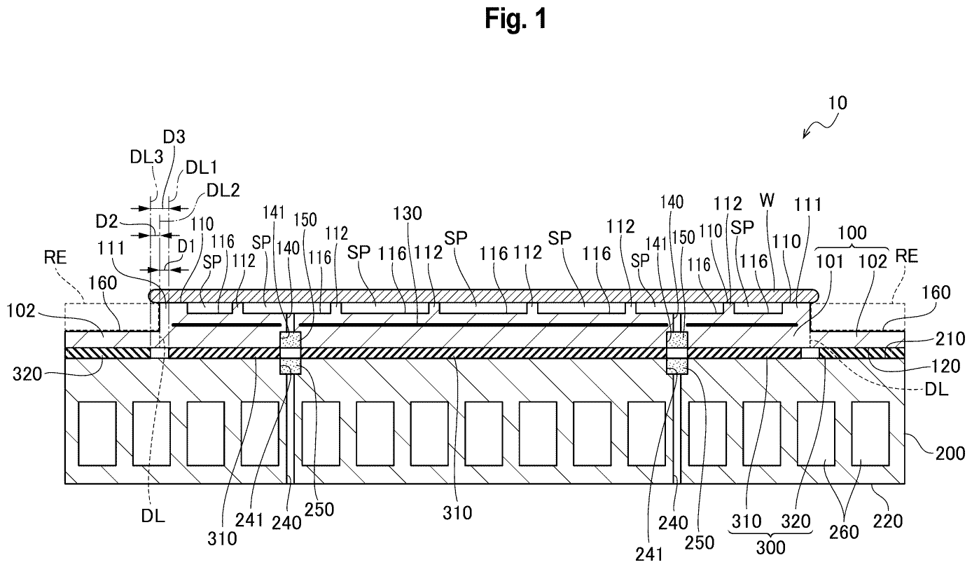

FIG. 1 is a cross sectional view schematically illustrating a configuration of the electrostatic chuck 10 in a state in which the wafer W is attracted and held. The electrostatic chuck 10 includes a dielectric substrate 100, a base plate 200, and a joining layer 300.

The dielectric substrate 100 is a substantially disk-shaped member formed of a ceramic sintered body. The dielectric substrate 100 contains, for example, highly pure aluminum oxide (Al₂O₃), but may contain other materials. A ceramics purity or type, an additive, or the like in the dielectric substrate 100 may be appropriately set by taking into account plasma resistance or the like needed for the dielectric substrate 100 in the semiconductor manufacturing apparatus.

A surface 110 on an upper side in FIG. 1 in the dielectric substrate 100 serves as a “placement surface” on which the wafer W is placed. A surface 120 on a lower side in FIG. 1 in the dielectric substrate 100 serves as a “surface to be joined” which is joined to the base plate 200 via the joining layer 300 which will be described later. A perspective in a case where the electrostatic chuck 10 is viewed from the surface 110 side along a direction perpendicular to the surface 110 will also be hereinafter expressed as “top view”.

The dielectric substrate 100 includes a first part 101 and a second part 102. The first part 101 is a substantially columnar part extending from the surface 110 toward a lower side in FIG. 1 to the surface 120. It can be said that the first part 101 is a part including the surface 110 as the placement surface in the dielectric substrate 100. In top view, an outer shape of the placement surface and an outer shape of the first part 101 may match each other, but need not necessarily match each other.

The second part 102 is an annular part projecting from an outer peripheral end of the first part 101 further toward an outer peripheral side, and is a part also called a “rim portion” of the dielectric substrate 100. In FIG. 1, a boundary between the first part 101 and the second part 102 is indicated by a dotted line DL. The second part 102 is thinner than the first part 101. The surface 120 described above is a surface on the lowermost side of the first part 101 in FIG. 1, and is also a surface on the lowermost side of the second part 102. A surface 160 on an uppermost side of the second part 102 is present at a position lower than the surface 110 in FIG. 1.

When processing on the wafer W is performed in the semiconductor manufacturing apparatus, an annular member RE that is called a “focus ring” and the like is arranged around the wafer W. The surface 160 of the second part 102 serves as a part that supports the annular member RE from a lower side. The surface 160 is a surface parallel to the surface 110.

An attraction electrode 130 is embedded inside the first part 101 of the dielectric substrate 100. The attraction electrode 130 is a thin planar layer made of a metallic material such as, for example, tungsten, and is arranged so as to be parallel to the surface 110. As a material of the attraction electrode 130, molybdenum, platinum, palladium, and the like may be used in addition to tungsten. When a voltage is applied to the attraction electrode 130 from an outside via a feed line which is not illustrated in the drawing, an electrostatic force is generated between the surface 110 and the wafer W, and according to this, the wafer W is attracted and held. The single attraction electrode 130 may be provided as so-called a “monopolar” electrode as in the present embodiment, but may also include two attraction electrodes as so-called “bipolar” electrodes.

Inside the second part 102, an internal electrode different from the attraction electrode 130 may be provided. Examples of such an internal electrode include, for example, an attraction electrode for generating an electrostatic force between itself and the annular member RE, an RF electrode, and the like.

As illustrated in FIG. 1, a space SP is formed between the dielectric substrate 100 and the wafer W. When a process such as etching is performed in the semiconductor manufacturing apparatus, an inert gas for temperature regulation is supplied to the space SP from the outside via a gas hole 140 or the like described later. When the inert gas is caused to be present between the dielectric substrate 100 and the wafer W, a thermal resistance between the dielectric substrate 100 and the wafer W is regulated, and according to this, a temperature of the wafer W is maintained at an appropriate temperature. As the inert gas for temperature regulation to be supplied to the space SP, a helium gas is used in the present embodiment, but the inert gas may be a gas of a type different from the helium gas.

A seal ring 111 and a dot 112 are provided on the surface 110 which serves as the placement surface, and the space SP described above is formed around the seal ring 111 and the dot 112.

The seal ring 111 is an annular protrusion provided as a wall defining the space SP at a position corresponding to the outermost circumference. An upper end of the seal ring 111 becomes a part of the surface 110 and abuts against the wafer W. It is noted that the seal ring 111 may include a plurality of seal rings 111 provided so as to divide the space SP. With such a configuration, a pressure of the helium gas in each of the spaces SP can be individually regulated, and a surface temperature distribution of the wafer W during the process can be set to be close to uniformity. In the present embodiment, an end part on the outer peripheral side of the seal ring 111 in top view matches an end part on the outer peripheral side of the first part 101.

A part denoted by reference sign “116” in FIG. 1 is a bottom of the space SP. Hereinafter, this part may also be referred to as a “bottom 116”. The seal ring 111 is formed as a result of digging a part of the surface 110 to a position of the bottom 116 together with the dot 112 which will be described next.

The dot 112 is a circular protrusion which protrudes from the bottom 116. The dot 112 includes a plurality of dots 112 to be provided. The plurality of dots 112 are substantially uniformly distributed and arranged on the placement surface of the dielectric substrate 100. An upper end surface of each of the dots 112 becomes a part of the surface 110 and abuts against the wafer W. By providing the plurality of thus configured dots 112, warping of the wafer W is reduced.

The gas hole 140 is formed in the dielectric substrate 100. The gas hole 140 is a through hole formed so as to extend in a direction perpendicular to the surface 110 serving as the placement surface. An end on the surface 110 side of the gas hole 140 is connected to the space SP. The gas hole 140 is a part of a flow path for supplying a helium gas toward the space SP. The gas hole 140 includes a plurality of gas holes 140 which are formed in the dielectric substrate 100, but FIG. 1 illustrates only two of the gas holes 140.

As illustrated in FIG. 1, a part on the surface 120 side of the gas hole 140 has an expanded diameter as compared with that of a part on the surface 110 side. The part having such an expanded diameter is also referred to as an “expanded-diameter part 141” hereinafter. An air-permeable plug 150 is arranged inside the expanded-diameter part 141. The air-permeable plug 150 is a porous body formed of, for example, alumina, and the entire plug is air-permeable. By arranging the air-permeable plug 150 as described above inside the gas hole 140, while a flow of the gas in the gas hole 140 is secured, occurrence of dielectric breakdown in a path through the gas hole 140 can be suppressed. Note that the part of the air-permeable plug 150 having air-permeability may be only a part of the air-permeable plug 150, instead of the entire plug. For example, only a part on a center side of the air-permeable plug 150 may have air-permeability, and a part on the outer peripheral side need not necessarily have air-permeability.

The base plate 200 is a substantially disk-shaped member which supports the dielectric substrate 100. The base plate 200 is made of, for example, a metallic material such as aluminum. A surface 210 on the upper side in FIG. 1 in the base plate 200 serves as a “surface to be joined” which is joined to the dielectric substrate 100 via the joining layer 300.

A coolant flow path 260 through which a coolant flows is formed inside the base plate 200. When the process such as etching is performed in the semiconductor manufacturing apparatus, the coolant is supplied from the outside to the coolant flow path 260, and according to this, the base plate 200 is cooled down. Heat generated in the wafer W during the process is transferred to the coolant via the helium gas in the space SP, the dielectric substrate 100, and the base plate 200, and the heat is exhausted to the outside together with the coolant. The supply and exhaustion of the coolant to and from the coolant flow path 260 are performed via openings which are not illustrated in the drawing and which are formed in a surface 220 opposite to the surface 210 in the base plate 200.

Gas holes 240 are formed in the base plate 200. The gas hole 240 is a through hole formed so as to extend perpendicularly from the surface 210 toward the surface 220 side on the opposite side thereof. The gas hole 240 is formed at each position overlapping the gas hole 140 of the dielectric substrate 100 in top view, and communicates with the gas hole 140 via a through hole provided in the joining layer 300. The gas hole 240 serves as a part of the flow path for supplying the helium gas toward the space SP together with the gas hole 140 of the dielectric substrate 100.

As illustrated in FIG. 1, a part on the surface 210 side of the gas hole 240 of the present embodiment has an expanded diameter as compared with that of a part on the surface 220 side. The part having such an expanded diameter is also referred to as an “expanded-diameter part 241” hereinafter. An air-permeable plug 250 is arranged inside the expanded-diameter part 241. The air-permeable plug 250 is a porous body formed of, for example, alumina, and the entire plug is air-permeable. By arranging the air-permeable plug 250 as described above inside the gas hole 240, while a flow of the gas in the gas hole 240 is secured, occurrence of dielectric breakdown in a path through the gas hole 240 can be suppressed. Note that the part of the air-permeable plug 250 having air-permeability may be only a part of the air-permeable plug 250, instead of the entire plug. For example, only a part on a center side of the air-permeable plug 250 may have air-permeability, and a part on the outer peripheral side need not necessarily have air-permeability.

The gas hole 240 may be formed so as to extend entirely in a linear shape as in the present embodiment, or may be formed so as to bend on a way from the surface 210 toward the surface 220. The plurality of gas holes 240 on the surface 210 side may be aggregated into a small number of flow paths inside the base plate 200, and the flow paths may be extended to the surface 220 side.

An insulating film may be formed on a surface of the base plate 200. The insulating film may be formed so as to cover only a part of the surface of the base plate 200, instead of the entire surface thereof. For example, the insulating film may be formed so as to cover only a side surface part excluding the surface 210 and the surface 220, that is, an exposed part exposed to plasma or the like inside the semiconductor manufacturing apparatus. Alternatively, the insulating film may be formed so as to cover a range including at least the entire surface 210. As the insulating film, for example, an alumina film formed by thermal spraying can be used. When the surface of the base plate 200 is covered by the insulating film, it is possible to increase dielectric withstand voltage of the base plate 200.

The joining layer 300 is a layer provided between the dielectric substrate 100 and the base plate 200 to join those components. The joining layer 300 is obtained by causing an adhesive made of an insulating material to be cured. In the present embodiment, a silicone adhesive is used as the above-described adhesive. It is noted however that the joining layer 300 may be obtained by causing an adhesive of other types to be cured. In any case, in order that a thermal resistance between the dielectric substrate 100 and the base plate 200 is reduced, a material with a highest possible thermal conductivity is preferably used as the material of the joining layer 300.

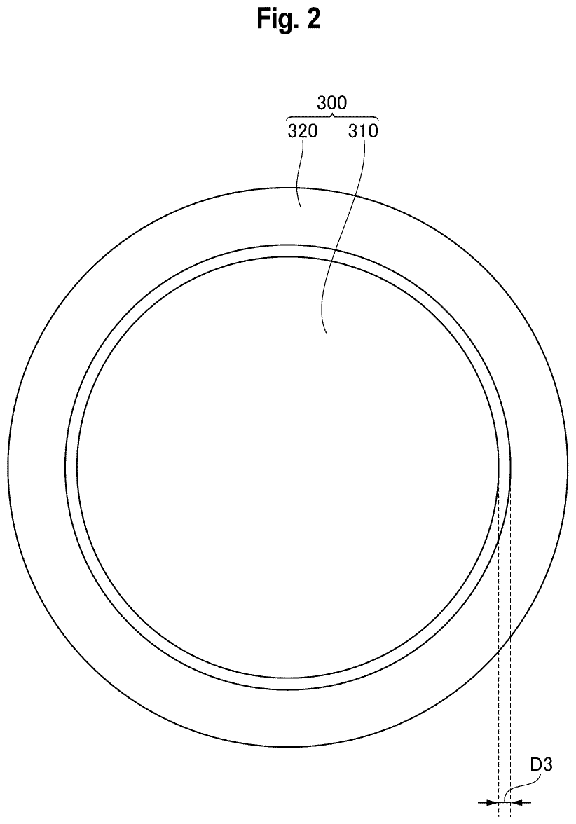

FIG. 2 schematically illustrates a configuration of the joining layer 300 in top view. The through holes are formed at respective parts of the joining layer 300 overlapping with the gas holes 140, overlapping with a lift pin hole (not illustrated), and the like, but the through holes are not illustrated in FIG. 2.

The joining layer 300 of the present embodiment includes a first joining layer 310 and a second joining layer 320. A shape of the first joining layer 310 in top view is a circular shape. In top view, a center of the first joining layer 310 matches the center of the dielectric substrate 100. The second joining layer 320 surrounds the first joining layer 310 in an annular shape on the outer peripheral side. An end part on the outer peripheral side of the first joining layer 310, an end part on the inner peripheral side of the second joining layer 320, and an end part on the outer peripheral side of the second joining layer 320 each have a circular shape in top view, and they are arranged concentrically.

A material of the first joining layer 310 and a material of the second joining layer 320 are different from each other. Specifically, the materials are selected so that a thermal conductivity of the second joining layer 320 is higher than a thermal conductivity of the first joining layer 310. Such a difference in thermal conductivity is achieved, for example, by making amounts of fillers to be put into the adhesive different from each other before the silicone adhesive to be the joining layer 300 is cured.

When processing is performed on the wafer W in the semiconductor manufacturing apparatus, it is preferable that fluctuation in an in-plane temperature distribution of the wafer W is as small as possible. However, during the process, a temperature of the wafer W tends to locally increase at a part on the outer peripheral side. Additionally, a temperature of the annular member RE arranged to surround the wafer W from the outer peripheral side often increases, and due to the influence thereof, a temperature of an outer peripheral side part of the wafer W may further increase. Thus, in the electrostatic chuck according to the present embodiment, by devising an arrangement of the first joining layer 310 and the second joining layer 320, it is possible to suppress a local temperature increase as described above.

A dash-dot line DL1 in FIG. 1 represents a position of the end part on the outer peripheral side of the first joining layer 310. A dash-dot line DL2 represents a position of the end part on the outer peripheral side of the first part 101. The “position of the end part on the outer peripheral side of the first part 101” may be read as the “position of the end part on the inner peripheral side of the second part 102”. A dash-dot line DL3 represents a position of the end part on the inner peripheral side of the second joining layer 320.

In the present embodiment, a shape and the like of the second joining layer 320 are set so that the end part on the inner peripheral side (dash-dot line DL3) of the second joining layer 320 is located at a position on the outer peripheral side in top view with respect to the end part on the outer peripheral side (dash-dot line DL2) of the first part 101. As a result, the end part on the inner peripheral side of the second joining layer 320 is located at a position not overlapping with the first part 101 in top view.

As described above, during the process of the wafer W, the temperature of the annular member RE surrounding the wafer W from the outer peripheral side is likely to increase. Additionally, along with a temperature increase of the annular member RE, a temperature of the outer peripheral side part of the wafer W may increase.

Thus, in the electrostatic chuck 10 according to the present embodiment, as described above, the end part on the inner peripheral side (dash-dot line DL3) of the second joining layer 320 is arranged at a position not overlapping with the first part 101 in top view. In the dielectric substrate 100, the first part 101 that supports the wafer W is joined to the base plate 200 via the first joining layer 310 having a low thermal conductivity, and the second part 102 that supports the annular member RE is joined to the base plate 200 via the second joining layer 320 having a high thermal conductivity. With such a configuration, a temperature increase of the annular member RE is suppressed, and a temperature increase of the outer peripheral side part of the wafer W due to the influence thereof is also suppressed, so that the in-plane temperature distribution of the wafer W can be made uniform.

In the dielectric substrate 100, the first part 101 that supports the wafer W does not overlap with the second joining layer 320 in top view. Due to this, it is possible to prevent a situation in which the outer peripheral side part of the wafer W is excessively cooled.

It should be noted that the position of the end part on the inner peripheral side (dash-dot line DL3) of the second joining layer 320 may match the position of the end part on the outer peripheral side (dash-dot line DL2) of the first part 101 in top view. Such a configuration is also included in a configuration in which the end part on the inner peripheral side of the second joining layer 320 is arranged at the “position not overlapping with the first part 101” in top view.

The positional relation between the second joining layer 320 and the first part 101 as described above may be established in at least all arbitrary cross sections including a central axis of the dielectric substrate 100 (that is, cross sections as in FIG. 1), but may be established only in any one of the cross sections including the central axis of the dielectric substrate 100. In other words, the end part on the inner peripheral side of the second joining layer 320 may be entirely located at a position not overlapping with the first part 101 in top view, but a part of the end part may be located at a position overlapping with the first part 101 in top view.

In the present embodiment, a shape and the like of the first joining layer 310 are set so that the end part on the outer peripheral side (dash-dot line DL1) of the first joining layer 310 is located at a position on the inner peripheral side in top view with respect to the end part on the outer peripheral side (dash-dot line DL2) of the first part 101. As a result, the end part on the outer peripheral side of the first joining layer 310 is located at a position not overlapping with the second part 102 in top view.

In such a configuration, the wafer W is cooled by the base plate 200 via only the first joining layer 310 of the joining layer 300, and the annular member RE is cooled by the base plate 200 via only the second joining layer 320 of the joining layer 300. Due to this, a material of the joining layer 300 can be easily optimized by selecting a material suitable for cooling the wafer W as the first joining layer 310 and selecting a material suitable for cooling the annular member RE as the second joining layer 320, for example.

It should be noted that the position of the end part on the outer peripheral side (dash-dot line DL1) of the first joining layer 310 may match the position of the end part on the outer peripheral side (dash-dot line DL2) of the first part 101 in top view. Such a configuration is also included in a configuration in which the end part on the outer peripheral side of the first joining layer 310 is arranged at the “position not overlapping with the second part 102” in top view.

In top view, a distance from the end part on the outer peripheral side (dash-dot line DL2) of the first part 101 to the end part on the outer peripheral side (dash-dot line DL1) of the first joining layer 310 is hereinafter also referred to as a “distance D1”. In top view, a distance from the end part on the outer peripheral side (dash-dot line DL2) of the first part 101 to the end part on the inner peripheral side (dash-dot line DL3) of the second joining layer 320 is hereinafter also referred to as a “distance D2”.

It is preferable that each of the distances D1 and D2 falls within a range of 1 mm or less. By making the distances D1 and D2 small to such a degree, it is possible to more reliably suppress local temperature increases of the annular member RE and the wafer W while optimizing the material of the joining layer 300 as described above.

In the present embodiment, the end part on the outer peripheral side (dash-dot line DL1) of the first joining layer 310 is separated from the end part on the inner peripheral side (dash-dot line DL3) of the second joining layer 320, and a space is formed therebetween. With such a configuration, when the dielectric substrate 100 and the base plate 200 are joined, the first joining layer 310 and the second joining layer 320, which are different kinds of adhesives, are prevented from being mixed, thereby preventing a situation in which their respective physical properties are changed.

A distance from the end part on the outer peripheral side (dash-dot line DL1) of the first joining layer 310 to the end part on the inner peripheral side (dash-dot line DL3) of the second joining layer 320 is hereinafter also referred to as a “distance D3”. To prevent a thermal resistance between the dielectric substrate 100 and the base plate 200 from being too large, the distance D3 is preferably kept at 2 mm or less. When mixing of the first joining layer 310 and the second joining layer 320 at the time of joining is not a problem, the distance D3 may be 0 mm. Furthermore, the joining layer 300 made of another material may be arranged between the first joining layer 310 and the second joining layer 320.

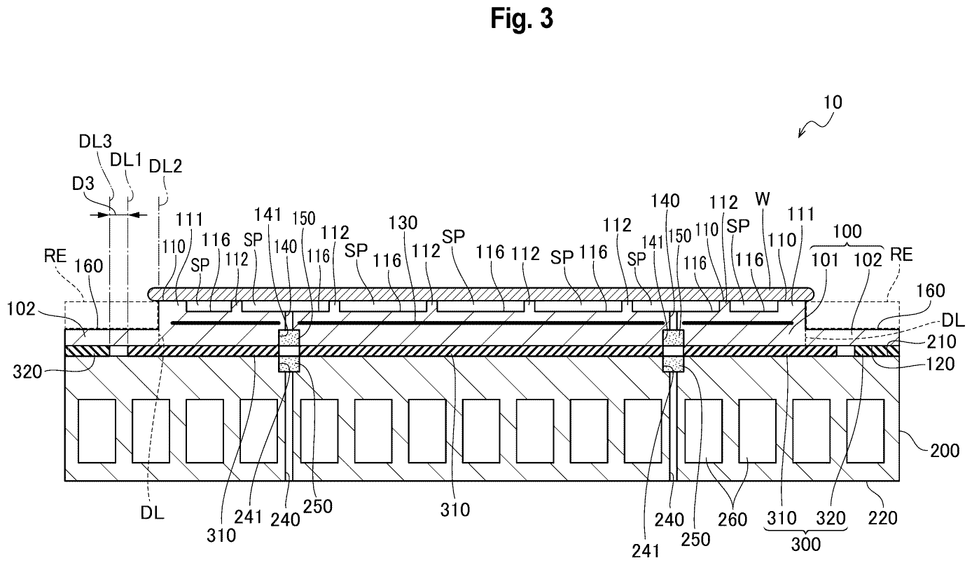

A second embodiment will be described with reference to FIG. 3. In the following, features different from those of the first embodiment will be mainly described, and description of features common to those of the first embodiment is omitted as appropriate.

The present embodiment is different from the first embodiment in the configuration of the joining layer 300. As illustrated in FIG. 3, in the present embodiment, the end part on the outer peripheral side (dash-dot line DL1) of the first joining layer 310 and the end part on the inner peripheral side (dash-dot line DL3) of the second joining layer 320 are both located at positions overlapping with the second part 102 in top view. As a result, a part on the inner peripheral side of the second part 102 supporting the annular member RE is joined to the base plate 200 via the first joining layer 310 having a low thermal conductivity, and a part on the outer peripheral side of the second part 102 is joined to the base plate 200 via the second joining layer 320 having a high thermal conductivity. In such a configuration, the annular member RE is cooled more efficiently at the part on the outer peripheral side as compared with the part on the inner peripheral side.

Depending on a configuration of the semiconductor manufacturing apparatus, due to fluctuation in an amount of incident heat from plasma or the like, a temperature of the outer peripheral side part of the annular member RE is likely to locally increase in some cases. In such a case, by employing the configuration of the present embodiment, a temperature increase of the outer peripheral side part of the annular member RE is suppressed, so that it is possible to make a temperature distribution of the annular member RE approximately uniform.

The present embodiment has been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate which includes a first part including a placement surface on which an object to be processed is placed, and a second part which protrudes from an outer peripheral end of the first part further toward an outer peripheral side and which is thinner than the first part;
a base plate joined to the dielectric substrate, and
a joining layer joining the dielectric substrate with the base plate, wherein the joining layer includes a first joining layer, and a second joining layer surrounding the first joining layer in an annular shape on an outer peripheral side,
a thermal conductivity of the second joining layer is higher than a thermal conductivity of the first joining layer, and
when viewed from a direction perpendicular to the placement surface,
an end part on an inner peripheral side of the second joining layer is located at a position not overlapping with the first part.

2. The electrostatic chuck according to claim 1, wherein
when viewed from the direction perpendicular to the placement surface,
an end part on the outer peripheral side of the first joining layer is located at a position overlapping with the second part.

3. The electrostatic chuck according to claim 1, wherein
when viewed from the direction perpendicular to the placement surface,
an end part on the outer peripheral side of the first joining layer is located at a position not overlapping with the second part.

4. The electrostatic chuck according to claim 1, wherein the first joining layer is separated from the second joining layer.

5. The electrostatic chuck according to claim 1, wherein
when viewed from the direction perpendicular to the placement surface,
a distance from an end part on the outer peripheral side of the first joining layer to an end part on the inner peripheral side of the second joining layer is equal to or smaller than 2 mm.

6. The electrostatic chuck according to claim 3, wherein
when viewed from the direction perpendicular to the placement surface,
a distance from an end part on the outer peripheral side of the first part to an end part on the outer peripheral side of the first joining layer is equal to or smaller than 1 mm, and
a distance from the end part on the outer peripheral side of the first part to an end part on the inner peripheral side of the second joining layer is equal to or smaller
